(19) United States
(12) Patent Application Publication
(10) Pub. No.: US 2020/0293280 A1
(43) Pub. Date: Sep. 17, 2020

(54) LOGARITHMIC COMPUTATION TECHNOLOGY THAT USES DERIVATIVES TO REDUCE ERROR

(71) Applicant: Intel Corporation, Santa Clara, CA (US)

(72) Inventors: Jorge Romero Aragon, Zapopan (MX); Xuebin Yang, Portland, OR (US); Carlos Flores Fajardo, Tlaquepaque (MX); Paulo Lopez Meyer, Zapopan (MX); Satish Jha, Portland, OR (US); Paulino Mendoza, Zapopan (US)

(73) Assignee: Intel Corporation, Santa Clara, CA (US)

(21) Appl. No.: 16/651,198

(22) PCT Filed: Dec. 1, 2017
(86) PCT No.: PCT/IB2017/057589

§ 371 Date: Mar. 26, 2020

(51) Int. Cl. G06F 7/483; G06F 7/487; G06F 7/556; G06F 11/16; H03K 17/693

(52) U.S. Cl. CPC G06F 7/4833; G06F 7/4873; H03K 17/693; G06F 11/1641; G06F 7/556

(57) ABSTRACT

Systems, apparatuses and methods may provide for technology that establishes a point of intersection based on a rate of change in a logarithmic function and generates a first linear estimation of the logarithmic function, wherein the first linear estimation has the point of intersection as an upper bound. Additionally, a second linear estimation of the logarithmic function may be generated, wherein the second linear estimation has the point of intersection as a lower bound. In one example, linear estimations of an antilogarithmic function may be similarly generated based on the rate of change of the antilogarithmic function.

### TECHNICAL FIELD

Embodiments generally relate to digital signal processing. More particularly, embodiments relate to logarithmic computation technology that uses derivatives to reduce error in digital signal processing architectures.

### BACKGROUND

Logarithms may be used to simplify arithmetic operations such as multiplication and/or division operations in digital signal processing architectures.

While approximations of logarithmic operations may reduce power, such approximations may also introduce error into the computational result.

### BRIEF DESCRIPTION OF THE DRAWINGS

The various advantages of the embodiments will become apparent to one skilled in the art by reading the following specification and appended claims, and by referencing the following drawings, in which:

FIG. 1 is a block diagram of an example of a digital signal processing apparatus according to an embodiment;

FIG. 2 is a flowchart of an example of a method of operating a logarithm converter according to an embodiment;

FIG. 3 is a schematic diagram of an example of a logarithm converter according to an embodiment;

FIG. 4 is a flowchart of an example of a method of operating an antilogarithm converter according to an embodiment;

FIG. 5 is a schematic diagram of an example of an antilogarithm converter according to an embodiment;

FIG. 6 is an illustration of an example of a semiconductor package apparatus according to an embodiment;

FIG. 7 is a block diagram of an example of a computing system according to an embodiment;

FIG. 8 is a plot of an example of an approximation error comparison according to an embodiment;

FIG. 9 is a plot of an example of a logarithm performance comparison according to an embodiment; and

FIG. 10 is a plot of an example of an antilogarithm performance comparison according to an embodiment.

### DESCRIPTION OF EMBODIMENTS

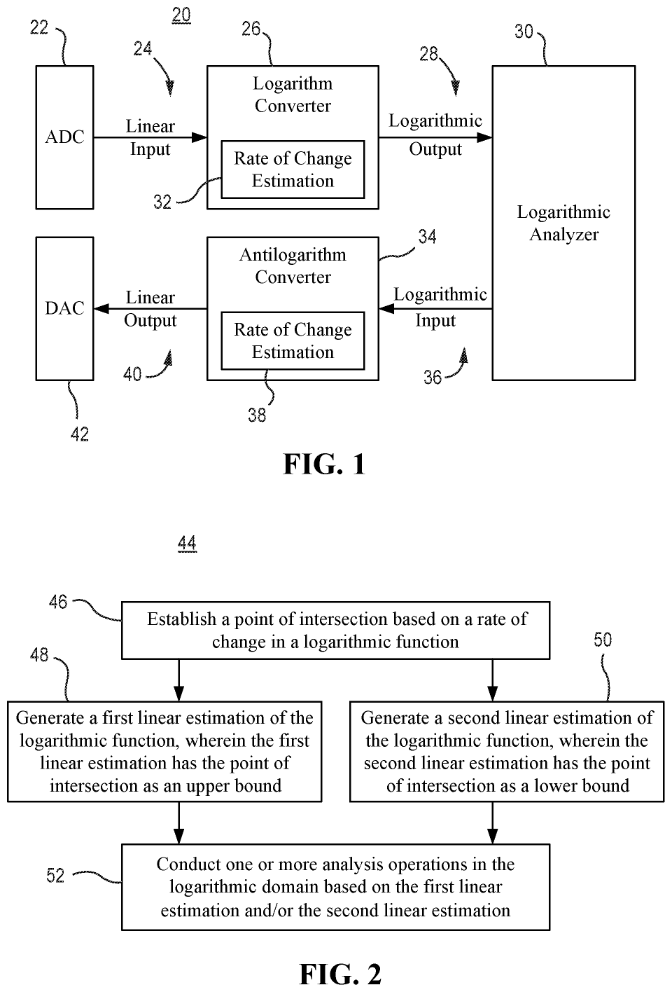

Turning now to FIG. 1, a digital signal processing apparatus 20 (e.g., digital signal processor/DSP) is shown. The digital signal processing apparatus 20 might be part of a datacenter server, desktop computer, notebook computer, tablet computer, convertible tablet, smart phone, mobile Internet device (MID), personal digital assistant (PDA), wearable computer, image capture device, media player, etc., or any combination thereof. In the illustrated example, a receiver chain of the apparatus 20 includes an analog-to-digital converter (ADC) 22 that samples an analog signal and generates a linear input 24, which may be converted into the logarithmic domain by a logarithm converter 26 (e.g., logarithmic conversion apparatus) in accordance with a particular logarithmic (e.g., “log”) function. A logarithmic output 28 of the logarithm converter 26 may be sent to a logarithmic analyzer 30 that conducts one or more arithmetic operations on the logarithmic output 28. The arithmetic operation(s) performed by the logarithmic analyzer 30 may be associated with a DSP application such as, for example, a speech processing, scientific computing, multimedia processing, computer graphics and/or artificial intelligence (AI, e.g., neural network) application. Performance of the arithmetic operation(s) in the logarithmic domain may simplify the operation of the apparatus 20.

As will be discussed in greater detail, the logarithm converter 26 may include a rate of change estimation 32 that is used to reduce error as well as power consumption in the apparatus 20. More particularly, the logarithmic function may be approximated in a “piecewise” fashion by a pair of intersecting lines, wherein the rate of change estimation 32 may be used to determine the point of intersection between the two lines. For example, selecting the middle of the rate of change in the logarithmic function as the point of intersection may identify the location where the logarithmic function is changing faster. Moreover, using the rate of change estimation 32 to establish the point of intersection may significantly enhance the accuracy (e.g., reduce the error) of the logarithmic output 28. Thus, if the apparatus 20 is deployed in, for example, a wireless application (e.g., wearable computer, handheld device using Long-Term Evolution/LTE technology to communicate), significant advantages might be achieved with regard to battery life and/or the end user experience.

The digital signal processing apparatus 20 may also include a transmitter chain having an antilogarithm converter 34 (e.g., antilogarithm estimation apparatus) that receives a logarithmic input 36 and uses a rate of change estimation 38 to convert the logarithmic input 36 into a linear output 40 (e.g., in the linear domain). As in the logarithm case, the antilogarithmic (e.g., “antilog”) function may be approximated in a piecewise fashion by a pair of intersecting lines, wherein the rate of change estimation 38 may enable a more effective determination of the point of intersection between the two lines. Thus, selecting the middle of the rate of change in the antilogarithmic function as the point of intersection may significantly enhance the accuracy of the linear output 40. While the discussions herein may reference two piecewise estimations, the solutions may also be applied to n piecewise estimations, where n is greater than two. In the illustrated example, a digital-to-analog converter (DAC) 42 converts the linear output 40 to an analog signal. The analog signal may be sent via, for example, a wireless link to another apparatus/platform (not shown).

### Logarithm Conversion

FIG. 2 shows a method 44 of operating a logarithm converter. The method 44 may generally be implemented in a digital processing apparatus such as, for example, the digital processing apparatus 20 (FIG. 1), already discussed. More particularly, the method 44 may be implemented as one or more modules in a set of logic instructions stored in a machine- or computer-readable storage medium such as random access memory (RAM), read only memory (ROM), programmable ROM (PROM), firmware, flash memory, etc., in configurable logic such as, for example, programmable logic arrays (PLAs), field programmable gate arrays (FPGAs), complex programmable logic devices (CPLDs), in fixed-functionality hardware logic using circuit technology such as, for example, application specific integrated circuit (ASIC), complementary metal oxide semiconductor (CMOS) or transistor-transistor logic (TTL) technology, or any combination thereof.

For example, computer program code to carry out operations shown in the method 44 may be written in any combination of one or more programming languages, including an object oriented programming language such as JAVA, SMALLTALK, C++ or the like and conventional procedural programming languages, such as the “C” programming language or similar programming languages. Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Illustrated processing block 46 provides for establishing a point of intersection based on a rate of change in a logarithmic function. In one example, block 46 selects the middle of the rate of change in the logarithmic function as the point of intersection. Block 48 may generate a first linear estimation of the logarithmic function, wherein the first linear estimation has the point of intersection as an upper bound. Additionally, block 50 may generate a second linear estimation of the logarithmic function, wherein the second linear estimation has the point of intersection as a lower bound.

More particularly, initial work on logarithmic approximations for digital computers was done by J. N. Mitchell (e.g., the “Mitchell approximation” work). As already noted, logarithmic domain digital signal processing may achieve complexity reduction.

In order to further improve accuracy, the Mitchell approximation may be modified with bit error correction solutions. The method 44 may generally provide an enhanced method to reduce the correction solution error by computing the derivative of the logarithmic function (and antilogarithmic function, as discussed below) and obtaining a better approximation compared to conventional solutions. Since the method 44 is based on selecting the point of intersection according to the rate of change of those functions (e.g., instead of selecting an arbitrary point) based on heuristics, the method 44 may achieve better conversion performance with lower complexity, better accuracy under similar conditions (e.g., two piecewise linear interpolation cases), and similar HW resources and/or memory usage compared to conventional solutions.

The method 44 may obtain an optimal trade-off between accuracy, performance and HW requirements. The Mitchell approximation may express that the base-2 logarithm of a binary number N (zₙ zₙ₋₁ zₙ₋₂, . . . , z₀. z₋₁ z₋₂ . . . z₋ₙ), with zₙ as the most significant nonzero bit of N, can be defined as:

log₂ N=n+log₂(1+x),

where x complies with 0≤x<1. The Mitchell approximation may propose that the logarithmic value can be obtained by detecting the position of the most significant nonzero bit of N, and using a linear approximation for log₂(1+x)≈x. The absolute error function of this approximation is:

ε(x)=log₂(1+x)−x,

where a maximum value of max(ε))=0.08639, results in only 3.5 bits of accuracy.

The method 44 may compute an approximation for log₂(1+x), based on the derivative of this function to determine the middle of the rate of change of this function (point of intersection), then conduct a piecewise linear approximation using two regions. The first phase may determine the intersection points by using:

$${f}^{′} ( x ) = \frac{d}{dx} {log}_{2} ( 1 + x ) = \frac{1}{1 + x} ( \frac{1}{ln ( 2 )} ) .$$

Then, the limits of the derivative for x (0≤x<1) may be evaluated; for x=0, ƒ′(0)=1.4427, and for x=1,ƒ′(1)=0.7213.

So, the intersection point between the two lines is:

$$\frac{{f}^{′} ( 0 ) + {f}^{′} ( 1 )}{2} = 1.082$$

The next process may be to determine the x value that is related with 1.082:

ƒ′(x)=0.082→ƒ′(0.3334)=1.082→x=0.3334

So, there may be three values of x of interest to be evaluated in the original function in order to obtain their corresponding pair:

ƒ(0)=log₂(1+0)=0

ƒ(0.3334)=log₂(1+0.3334)=0.4114

ƒ(1)=log₂(1+1)=1

The result is therefore the three pair of points for the intersecting lines: (0,0), (0.3334,0.4114) and (1,1).

There is a well-known math equation for the lines based on a point and the slope:

y−y₁=m(x−x₁)

Where m is the slope, and (x₁,y₁) is point that the line is crossing. To generate the first line equation L₁ (e.g., first linear estimation), we have (0,0) and (0.3334, 0.4114). So, the slope may be calculated using these points:

$$m = \frac{0.4114}{0.3334} = 1.246$$

And then the point (0,0) and this slope may be used to obtain the line equation L₁ based on the above point and slope equation:

L₁(x)−0=1.246(x−0)→L₁(x)=1.246x

The same approach may be applied for the second line equation L₂ (e.g., second linear estimation) using (0.3334,0.4114) and (1,1):

$$m = \frac{1 - 0.4114}{1 - 0.3334} = 0.8785$$

$${L}_{2} ( x ) - 1 = 0.8785 ( x - 1 ) \to {L}_{2} ( x ) = 0.8785 x + 0.1215$$

Thus, the piecewise linear approximation may be:

L₁(x)=1.246x,{0≤x<0.3334}≈log₂(1+x),{0≤x<0.3334},

L₂(x)=0.8785+0.1215,{0.3334≤x<1}≈log₂(1+x),{0.3334≤x<1},

To simplify the HW implementation, the coefficients may be approximated using fixed-point arithmetic logic, wherein the final equation may be expressed by:

$${log}_{2} ( 1 + x ) \approx \{ \begin{matrix}1.246 x \approx x + \frac{1}{4} {x}_{4 mab} , \{ 0 \leq x < 0.3334 \} \\ 0.8785 x + 0.1215 \approx x - \frac{1}{8} {x}_{4 mab} + \frac{1}{8} , \{ 0.3334 \leq x < 1 \}\end{matrix} ,$$

where x_{4msb} represents only the four most significant bits of x.

Illustrated block 52 conducts one or more analysis operations in the logarithmic domain based on the first linear estimation and/or the second linear estimation. Block 52 may include conducting simplified mathematical operations associated with a speech processing, scientific computing, multimedia processing, computer graphics, AI and/or other DSP application.

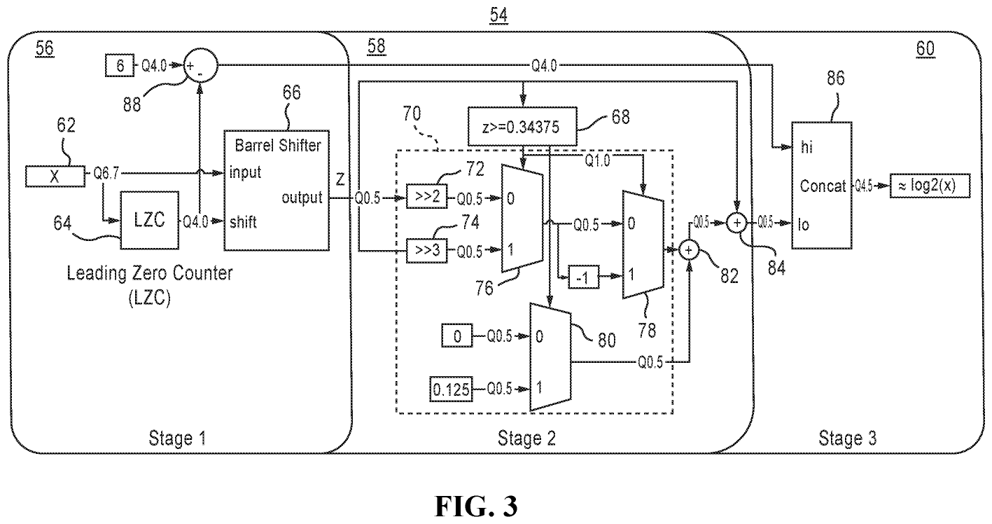

FIG. 3 shows a logarithm converter 54 that may be used to achieve the above linear estimations. The logarithm converter 54 may generally include logic (e.g., configurable logic and/or fixed-functionality hardware logic) that implements one or more aspects of the method 44 (FIG. 2), already discussed. The illustrated logarithm converter 54, which may be readily substituted for the logarithm converter 26 (FIG. 1), generally includes an input stage 56 (“Stage 1”), an intermediate stage 58 (“Stage 2”), and an output stage 60 (“Stage 3”). The input stage 56 may receive a linear input 62 (“x”) containing, for example, six integer bits and seven fractional bits (e.g., Q6.7). A leading zero counter (LZC) 64 may identify the four most significant bits (MSB, e.g., Q4.0) to a barrel shifter 66, which outputs five fractional bits (z, e.g., Q0.5) to the intermediate stage 58.

The illustrated intermediate stage 58 includes a comparator 68 to establish the point of intersection (e.g., 0.34375 approximating 0.3334) and a multiplexer arrangement 70 coupled to the comparator 68, wherein the multiplexer arrangement 70 generates the first linear estimation and the second linear estimation. More particularly, the multiplexer arrangement 70 may include a first shifter 72 to conduct a divide operation (e.g., 1/4 in the above 1/4x_{4msb} term) with respect to the first linear estimation, a second shifter 74 to conduct a divide operation (e.g., 1/8 in the above 1/8 x_{4msb} term) with respect to the second linear estimation, and a first multiplexer 76 to select between the first shifter 72 and the second shifter 74. Additionally, the multiplexer arrangement 70 may include a second multiplexer 78 to select between the output of the first multiplexer 76 and a negated output of the first multiplexer 76. The negated output may be obtained by performing a two's complement operation on the output of the first multiplexer 76.

In the illustrated example, the multiplexer arrangement 70 also includes a third multiplexer 80 to select between a first constant value (zero) associated with the first linear estimation and a second constant value (0.125, e.g., the 1/8 term) associated with the second linear estimation. A first adder 82 (e.g., constant adder) may sum the terms output by the multiplexer arrangement 70 and a second adder 84 may sum the output of the first adder 82 with the fractional bits output by the input stage 56. Additionally, the output stage 60 may include a concatenator 86 to combine the fractional bits (e.g., Q0.5) obtained from the intermediate stage with the four most significant bits (e.g., Q4.0) obtained from an adder 88 in the input stage.

### Antilogarithm Conversion

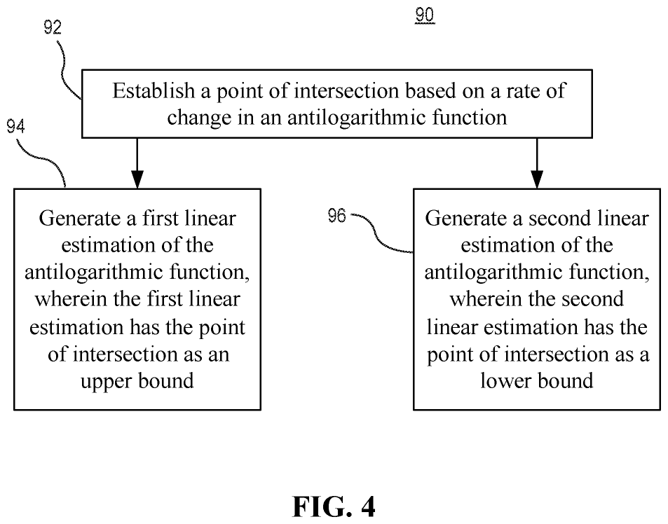

FIG. 4 shows a method 90 of operating an antilogarithmic converter. The method 90 may generally be implemented in a digital processing apparatus such as, for example, the digital processing apparatus 20 (FIG. 1), already discussed. More particularly, the method 90 may be implemented as one or more modules in a set of logic instructions stored in a non-transitory machine- or computer-readable storage medium such as RAM, ROM, PROM, flash memory, etc., in configurable logic such as, for example, PLAs, FPGAs, CPLDs, in fixed-functionality hardware logic using circuit technology such as, for example, ASIC, CMOS or TTL technology, or any combination thereof.

Illustrated processing block 92 provides for establishing a point of intersection based on a rate of change in an antilogarithmic function. In one example, block 92 selects the middle of the rate of change in the antilogarithmic function as the point of intersection. Block 94 may generate a first linear estimation of the antilogarithmic function, wherein the first linear estimation has the point of intersection as an upper bound. Additionally, block 96 may generate a second linear estimation of the logarithmic function, wherein the second linear estimation has the point of intersection as a lower bound.

The Mitchell approximation may propose that a binary antilogarithmic value can be obtained by:

2^{x}≈2^{x}^{ᵢ}·(x_{ƒ}+1)

Where xᵢ and x_{ƒ} denote the integer and fractional part of x, respectively. Although the approximation may be implemented with only a shifter (right or left according to the sign of x) and an adder, the approximation may result in relatively low accuracy unless enhanced as described herein. To improve accuracy, the function g(x_{ƒ})=(x_{ƒ}+1) may be approximated with a piecewise linear solution. As above, the piecewise linear solution may also be based on the derivatives of ƒ(x_{ƒ})=2^{x}^{_{ƒ}} to determine line equation coefficients. It may be assumed that x_{ƒ} is defined only in the range of 0≤x_{ƒ}<1.

The derivative of ƒ(x_{ƒ}) may be denoted by:

$${f}^{′} ( {x}_{f} ) = \frac{d}{{dx}_{f}} {2}^{{x}_{f}} = {2}^{{x}_{f}} ln ( 2 ) ,$$

as in the logarithmic approximation case described above, the derivative may be evaluated in the limits of the range 0≤x_{ƒ}<1. For x_{ƒ}=0, ƒ′(0)=ln(2) and for x_{ƒ}=1, ƒ′(1)=2 ln(2).

The middle point is

$$\frac{{f}^{′} ( 0 ) + {f}^{′} ( 1 )}{2} = \frac{3}{2} ln ( 2 ) ,$$

By using the derivative function, the corresponding x_{ƒ} value for the middle point and its correspondent evaluation of ƒ(x_{ƒ}) is:

$${f}^{′} ( {x}_{f} ) = {2}^{{x}_{f}} ln ( 2 ) = \frac{3}{2} ln ( 2 ) \to {x}_{f} = {log}_{2} ( \frac{3}{2} ) = 0.585 , \\ and$$

$$f ( 0.585 ) = \frac{3}{2} .$$

Then, the original expression may be evaluated at the three points of interest 0, 0.585 and 1:

ƒ(0)=2⁰=1

ƒ(0.585)=2^{0.585}=3/2

ƒ(1)=2¹=2

Accordingly, the three points are (0,1), (0.585,1.5) and (1,2) and may be used to generate L₁ and L₂ following the point and slope equation, as already discussed:

$$m = \frac{1.5 - 1}{0.585} = 0.8547$$

$${L}_{1} ( x ) - 1 = 0.8547 ( x - 0 ) \to {L}_{1} ( x ) = 0.8547 x + 1$$

$$m = \frac{2 - 1.5}{1 - 0.585} = 1.2048$$

$${L}_{2} ( x ) - 2 = 1.2048 ( x - 1 ) \to {L}_{2} ( x ) = 1.2048 x + 0.7952$$

To simplify the HW implementation, fix point arithmetic may be used, and the approximations may be expressed by:

$$( {x}_{f} + 1 ) = \{ \begin{matrix}0.8547 {x}_{f} + 1 \approx 1 + \frac{1}{2} {x}_{f 7 mab} + \frac{1}{4} {x}_{f 7 mab} + \frac{1}{16} {x}_{f 7 mab} ( 0 \leq {x}_{f} < 0.585 ) \\ 1.2048 {x}_{f} + 0.7952 = {x}_{f} + \frac{1}{8} {x}_{f 7 mab} + \frac{1}{16} {x}_{f 7 mab} + 0.7969 ( 0.585 \leq {x}_{f} < 1 )\end{matrix} ,$$

where x_{ƒ7msb} represents only the seven most significant bits of x_{ƒ}.

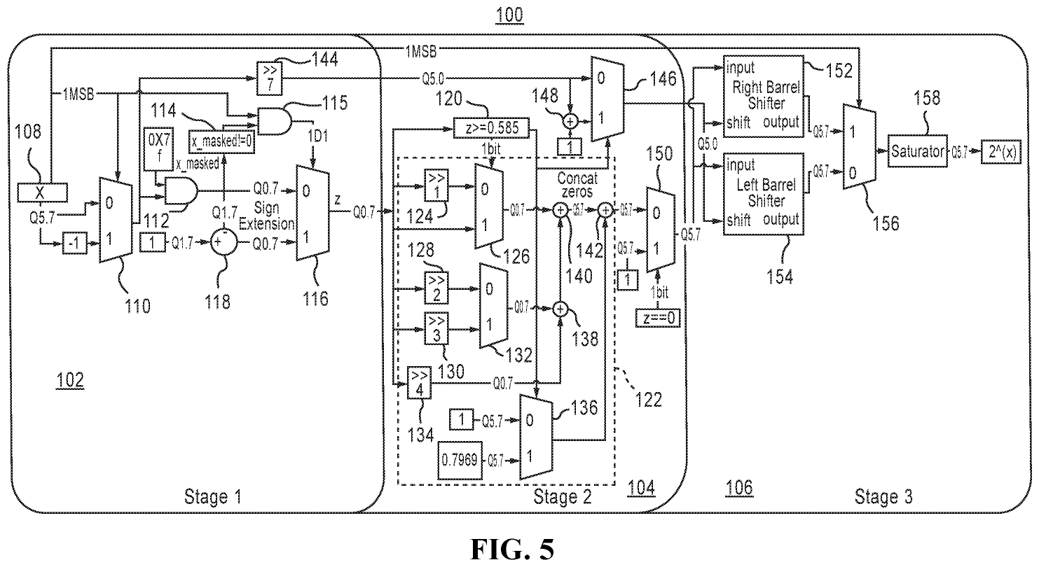

Turning now to FIG. 5, an antilogarithm converter 100 is shown. The antilogarithm converter 100 may generally include logic (e.g., configurable logic and/or fixed-functionality hardware logic) that implements one or more aspects of the method 90 (FIG. 24). The illustrated antilogarithm converter 100 may be readily substituted for the antilogarithm converter 34 (FIG. 1), already discussed. In one example, the antilogarithm converter 100 includes an input stage 102, an intermediate stage 104 and an output stage 106.

The input stage 102 may receive a logarithmic input 108 (“x”) containing, for example, five integer bits and seven fractional bits (e.g., Q5.7). The input stage 102 may generally determine the sign of the logarithmic input 108 (e.g., digital input value) and extract a fractional portion from the logarithmic input 108 based on the sign. More particularly, a multiplexer 110 may use the most significant bit (MSB), which indicates whether the logarithmic input 108 is positive or negative, to select between the logarithmic input 108 and a negated logarithmic input 108. The negated logarithmic input 108 may be obtained by performing a two's complement operation on the logarithmic input 108.

An AND gate 112 may use a mask having the value of 0x7f to extract the fractional portion (e.g., seven bits) of the logarithmic input 108, wherein the fractional portion may be provided to a comparator 114, another multiplexer 116 and a constant adder 118. The illustrated constant adder 118 subtracts the fractional portion from the value one and applies the result as an input to the multiplexer 116. The comparator 114 may determine whether the fractional portion is zero. If the fractional portion is zero and the logarithmic input 108 is negative, an AND gate 115 may instruct the illustrated multiplexer 116 to pass the zero value to the intermediate stage 104. Otherwise, the multiplexer 116 may pass the fractional portion to the intermediate stage 104.

The illustrated intermediate stage 104 generally includes a comparator 120 to establish the point of intersection (e.g., the middle of the rate of change based on the derivative of the antilogarithmic function) and a multiplexer arrangement 122 coupled to the comparator 120, wherein the multiplexer arrangement 122 generates a first linear estimation and a second linear estimation. In one example, the multiplexer arrangement 122 includes a first shifter 124 to conduct a first divide operation (e.g., 1/2 in the above 1/2x_{ƒ7msb} term) on a fractional portion of the logarithmic input 108 with respect to the first linear estimation and a first multiplexer 126 to select between an output of the first shifter 124 and the fractional portion (e.g., x_{f}). The multiplexer arrangement 122 may also include a second shifter 128 to conduct a second divide operation (e.g., 1/4 in the above 1/4x_{f7msb} term) on the fractional portion with respect to the first linear estimation, a third shifter 130 to conduct a third divide operation (e.g., 1/8 in the above 1/8x_{f7msb} term) on the fractional portion with respect to the second linear estimation, and a second multiplexer 132 to select between the output of the second shifter 128 and the output of the third shifter 130.

The illustrated multiplexer arrangement 122 also includes a fourth shifter 134 to conduct a fourth divide operation (e.g., 1/16 in the above 1/16x_{ƒ7msb} terms) on the fractional portion with respect to the first linear estimation and the second linear estimation. The multiplexer arrangement 122 may also include a third multiplexer 136 to select between a first constant value (one) associated with the first linear estimation and a second constant value (0.7969) associated with the second linear estimation. An adder 138 may sum the output of the fourth shifter 134 with the output of the second multiplexer, an adder 140 may sum the output of the adder 140 with the output of the first multiplexer 126, and a constant adder 142 may sum the output of the adder 138 with the output of the third multiplexer 136. A fourth multiplexer 150 may pass the output of the constant adder 142 to the output stage 106 if the fractional portion of the logarithmic input 108 is not equal to zero, and pass the value one to the output stage 106 if the fractional portion of the logarithmic input 108 is equal to zero.

The input stage 102 may also include a shifter 144 that provides the integer portion of the logarithmic input 108 to a multiplexer 146 in the intermediate stage 104. The multiplexer 146 may select between the output of the shifter 144 and the output of a constant adder 148 that performs a two's complement on the output of the shifter 144.

The illustrated output stage 106 conducts a barrel shift operation on either the first linear estimation or the second linear estimation based on the sign of the logarithmic input 108. More particularly, the output stage 106 may include a right barrel shifter 152 that right-shifts the output of the fourth multiplexer 150 by the amount of the value obtained from the output of the multiplexer 146 and a left barrel shifter 154 that left-shifts the output of the fourth multiplexer 150 by the amount of the value obtained from the output of the multiplexer 146. Additionally, a multiplexer 156 may select the output of the right barrel shifter 152 if the logarithmic input 108 is positive and the output of the left barrel shifter 154 if the logarithmic input 108 is negative.

In one example, the output of the multiplexer 156 is coupled to a saturator 158. In this regard, boundaries may be defined for the computation of the antilogarithm operation due to the fixed-point representation. Thus, if the logarithmic input 108 is less than the negative value of the number of fractional bits (e.g., minus seven), the output may be set to zero. If, however, the logarithmic input 108 is greater than or equal to number of integer bits (e.g., 5−1=4), the output may be set to the maximum number that can be represented using the current fixed-point representation (e.g., 15.9921875).

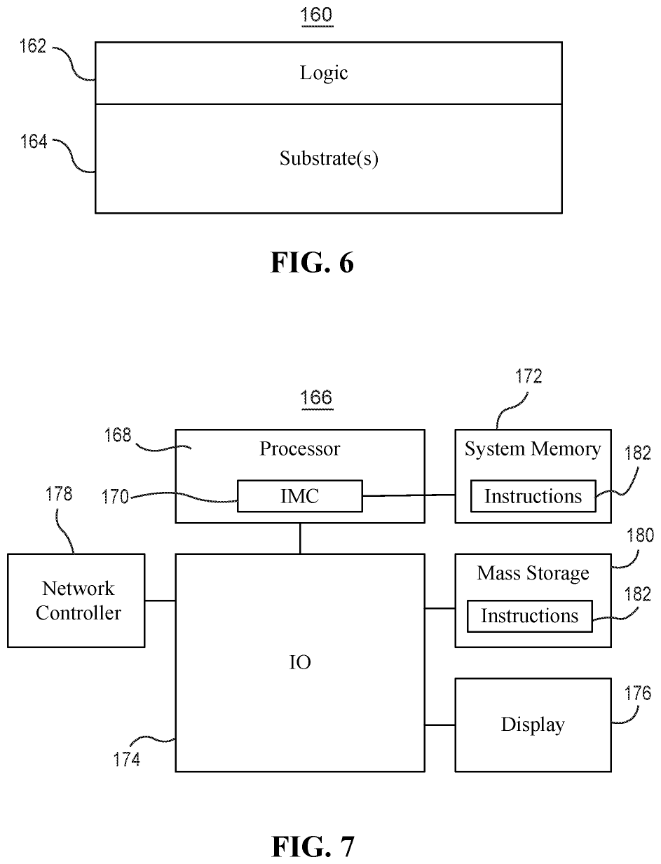

FIG. 6 shows a semiconductor package apparatus 160. The apparatus 160 may implement one or more aspects of the method 44 (FIG. 2) and/or the method 90 (FIG. 4) and may be readily substituted for the digital processing apparatus 20 (FIG. 1), already discussed. The illustrated apparatus 160 includes one or more substrates 164 (e.g., silicon, sapphire, gallium arsenide) and logic 162 (e.g., transistor array and other integrated circuit/IC components) coupled to the substrate(s) 164. The logic 162 may be implemented at least partly in configurable logic or fixed-functionality logic hardware. In one example, the logic 162 includes transistor channel regions that are positioned (e.g., embedded) within the substrate(s). Thus, the interface between the logic 162 and the substrate(s) 164 may not be an abrupt junction. The logic 162 may also be considered to include an epitaxial layer that is grown on an initial wafer of the substrate(s).

Turning now to FIG. 7, an accuracy-enhanced computing system 166 is shown. The computing system 166 may generally be part of an electronic device/platform having computing functionality (e.g., PDA, notebook computer, tablet computer, server), communications functionality (e.g., smart phone), imaging functionality, media playing functionality (e.g., smart television/TV), wearable functionality (e.g., watch, eyewear, headwear, footwear, jewelry), vehicular functionality (e.g., car, truck, motorcycle), etc., or any combination thereof. In the illustrated example, the system 166 includes a host processor 168 (e.g., central processing unit/CPU) having an integrated memory controller (IMC) 170 that is coupled to a system memory 172.

The illustrated system 166 also includes an input output (IO) module 174 implemented together with the processor 168 on a semiconductor die (not shown) as a system on chip (SoC), wherein the IO module 174 functions as a host device and may communicate with, for example, a display 176 (e.g., touch screen, liquid crystal display/LCD, light emitting diode/LED display), a network controller 178 (e.g., wired and/or wireless), and an mass storage 180 (e.g., hard disk drive/HDD, optical disk, solid state drive/SSD, flash memory). The system memory 172 and/or the mass storage 180 may include a set of instructions 182, which when executed by the processor 168 and/or the IO module 174, cause the computing system 166 to perform one or more aspects of the method 44 (FIG. 2) and/or the method 90 (FIG. 4). Thus, execution of the instructions 182 may cause the computing system 166 to establish a point of intersection based one a rate of change in a logarithmic function, generate a first linear estimation of the logarithmic function, and generate a second linear estimation of the logarithmic function, wherein the first linear estimation has the point of intersection as an upper bound and the second linear estimation has the point of intersection as a lower bound.

Additionally, execution of the instructions 182 may cause the computing system 166 to establish a point of intersection based on a rate of change in an antilogarithmic function, generate a first linear estimation of the antilogarithmic function, and generate a second linear estimation of the antilogarithmic function, wherein the first linear estimation has the point of intersection as an upper bound and the second linear estimation has the point of intersection as a lower bound.

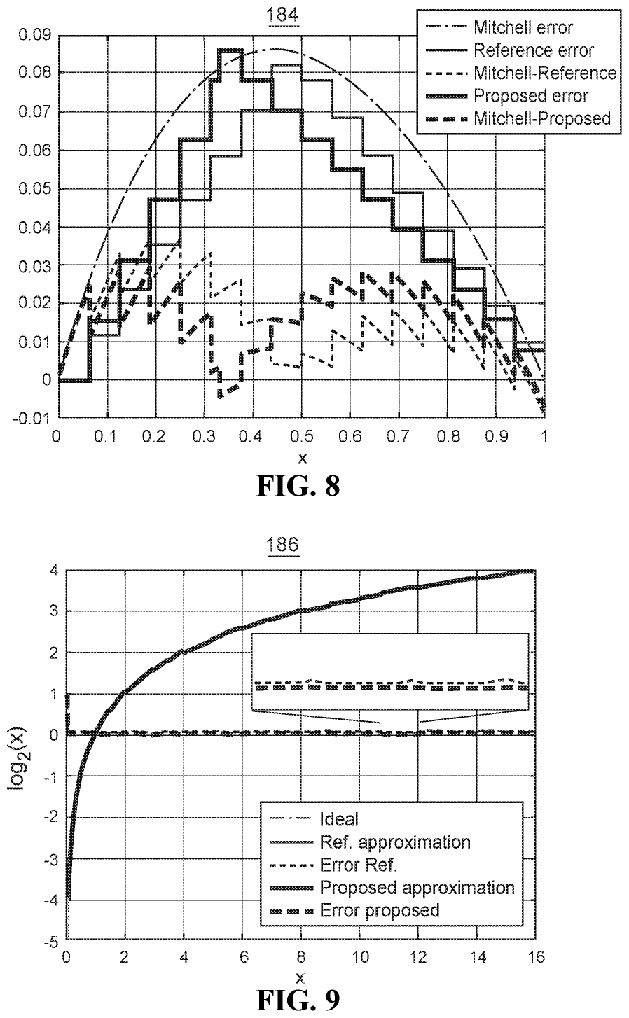

FIG. 8 shows a plot 184 of an example of an approximation error for a logarithmic function. The plot 184 demonstrates that the proposed error may be significantly reduced and that the relative error against the Mitchell approximation may be increased.

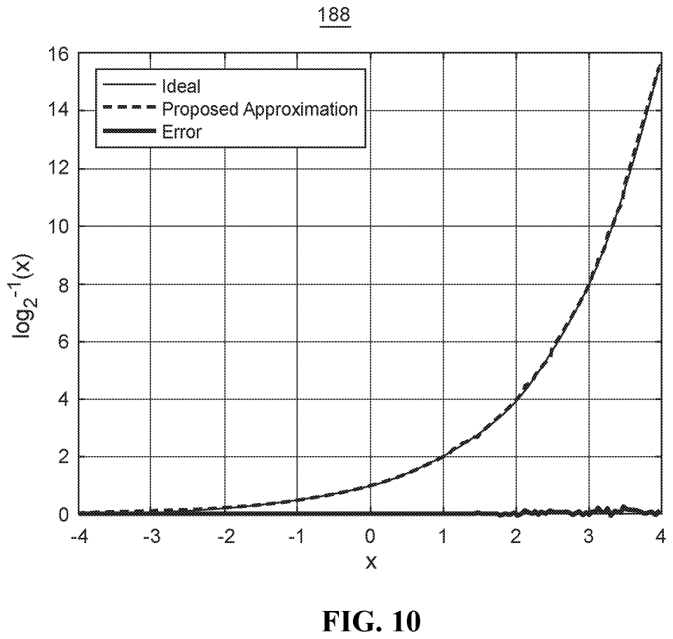

FIGS. 9 and 10 show plots 186 and 188 of examples of logarithm and antilogarithm performance comparisons, respectively. The plots 186 and 188 demonstrate that accuracy may be significantly enhanced via the technology described herein.

### ADDITIONAL NOTES AND EXAMPLES

Example 1 may include a logarithmic estimation apparatus comprising one or more substrates and logic coupled to the one or more substrates, wherein the logic is implemented in one or more of configurable logic or fixed-functionality hardware logic, the logic coupled to the one or more substrates to establish a point of intersection based on a rate of change in a logarithmic function, generate a first linear estimation of the logarithmic function, wherein the first linear estimation has the point of intersection as an upper bound, and generate a second linear estimation of the logarithmic function, wherein the second linear estimation has the point of intersection as a lower bound.

Example 2 may include the logarithmic estimation apparatus of Example 1, wherein the logic coupled to the one or more substrates includes a comparator to establish the point of intersection, and a multiplexer arrangement coupled to the comparator, wherein the multiplexer arrangement is to generate the first linear estimation and the second linear estimation.

Example 3 may include the logarithmic estimation apparatus of Example 2, wherein the multiplexer arrangement includes a first shifter to conduct a divide operation with respect to the first linear estimation, a second shifter to conduct a divide operation with respect to the second linear estimation, and a first multiplexer to select between the first shifter and the second shifter.

Example 4 may include the logarithmic estimation apparatus of Example 3, wherein the multiplexer arrangement includes a second multiplexer to select between an output of the first multiplexer and a negated output of the first multiplexer.

Example 5 may include the logarithmic estimation apparatus of Example 2, wherein the multiplexer arrangement includes a third multiplexer to select between a first constant value associated with the first linear estimation and a second constant value associated with the second linear estimation.

Example 6 may include the logarithmic estimation apparatus of any one of Examples 1 to 5, wherein the logic coupled to the one or more substrates is to select a middle of the rate of change in the logarithmic function as the point of intersection.

Example 7 may include a method of operating a logarithmic estimation apparatus, comprising establishing a point of intersection based on a rate of change in a logarithmic function, generating a first linear estimation of the logarithmic function, wherein the first linear estimation has the point of intersection as an upper bound, and generating a second linear estimation of the logarithmic function, wherein the second linear estimation has the point of intersection as a lower bound.

Example 8 may include the method of Example 7, wherein the point of intersection is established via a comparator, and wherein the first linear estimation and the second linear estimation are generated via a multiplexer arrangement coupled to the comparator.

Example 9 may include the method of Example 8, further including conducting, via a first shifter of the multiplexer arrangement, a divide operation with respect to the first linear estimation, conducting, via a second shifter of the multiplexer arrangement, a divide operation with respect to the second linear estimation, and selecting, via a first multiplexer of the multiplexer arrangement, between the first shifter and the second shifter.

Example 10 may include the method of Example 9, further including selecting, via a second multiplexer of the multiplexer arrangement, between an output of the first multiplexer and a negated output of the first multiplexer.

Example 11 may include the method of Example 8, further including selecting, via a third multiplexer of the multiplexer arrangement, between a first constant value associated with the first linear estimation and a second constant value associated with the second linear estimation.

Example 12 may include the method of any one of Examples 7 to 11, wherein establishing the point of intersection includes selecting a middle of the rate of change in the logarithmic function as the point of intersection.

Example 13 may include an antilogarithmic estimation apparatus comprising one or more substrates, and logic coupled to the one or more substrates, wherein the logic is implemented in one or more of configurable logic or fixed-functionality hardware logic, the logic coupled to the one or more substrates to establish a point of intersection based on a rate of change in an antilogarithmic function, generate a first linear estimation of the antilogarithmic function, wherein the first linear estimation has the point of intersection as an upper bound, and generate a second linear estimation of the antilogarithmic function, wherein the second linear estimation has the point of intersection as a lower bound.

Example 14 may include the antilogarithmic estimation apparatus of Example 13, wherein the logic coupled to the one or more substrates includes a comparator to establish the point of intersection, and a multiplexer arrangement coupled to the comparator, wherein the multiplexer arrangement is to generate the first linear estimation and the second linear estimation.

Example 15 may include the antilogarithmic estimation apparatus of Example 14, wherein the multiplexer arrangement includes a first shifter to conduct a first divide operation on a fractional portion of a digital input value with respect to the first linear estimation, a first multiplexer to select between an output of the first shifter and the fractional portion, a second shifter to conduct a second divide operation on the fractional portion with respect to the first linear estimation, a third shifter to conduct a third divide operation on the fractional portion with respect to the second linear estimation, a second multiplexer to select between an output of the second shifter and an output of the third shifter, a fourth shifter to conduct a fourth divide operation on the fractional portion with respect to the first linear estimation and the second linear estimation, and a third multiplexer to select between a first constant value associated with the first linear estimation and a second constant value associated with the second linear estimation.

Example 16 may include the antilogarithmic estimation apparatus of Example 13, wherein the logic coupled to the one or more substrates includes an input stage to determine a sign of a digital input value and extract a fractional portion from the digital input value based on the sign.

Example 17 may include the antilogarithmic estimation apparatus of Example 16, wherein the logic coupled to the one or more substrates further includes an output stage to conduct a barrel shift operation on either the first linear estimation or the second linear estimation based on the sign of the digital input value.

Example 18 may include the antilogarithmic estimation apparatus of any one of Examples 13 to 17, wherein the logic coupled to the one or more substrates is to select a middle of the rate of change in the antilogarithmic function as the point of intersection.

Example 19 may include a method of operating an antilogarithmic estimation apparatus, comprising establishing a point of intersection based on a rate of change in an antilogarithmic function, generating a first linear estimation of the antilogarithmic function, wherein the first linear estimation has the point of intersection as an upper bound, and generating a second linear estimation of the antilogarithmic function, wherein the second linear estimation has the point of intersection as a lower bound.

Example 20 may include the method of Example 19, wherein the point of intersection is established via a comparator, and wherein the first linear estimation and the second linear estimation are generated by a multiplexer arrangement coupled to the comparator.

Example 21 may include the method of Example 20, further including conducting, via a first shifter, a first divide operation on a fractional portion of a digital input value with respect to the first linear estimation, selecting, via a first multiplexer, between an output of the first shifter and the fractional portion, conducting, via a second shifter, a second divide operation on the fractional portion with respect to the first linear estimation, conducting, via a third shifter, a third divide operation on the fractional portion with respect to the second linear estimation, selecting, via a second multiplexer, between an output of the second shifter and an output of the third shifter, conducting, via a fourth shifter, a fourth divide operation on the fractional portion with respect to the first linear estimation and the second linear estimation, and selecting, via a third multiplexer, between a first constant value associated with the first linear estimation and a second constant value associated with the second linear estimation.

Example 22 may include the method of Example 19, further including determining, via an input stage, a sign of a digital input value, and extracting, via the input stage, a fractional portion from the digital input value based on the sign.

Example 23 may include the method of Example 22, further including conducting, via an output stage, a barrel shift operation on either the first linear estimation or the second linear estimation based on the sign of the digital input value.

Example 24 may include the method of any one of Examples 19 to 23, wherein establishing the point of interjecting includes selecting a middle of the rate of change in the logarithmic function as the point of intersection.

Example 25 may include an apparatus comprising means for performing the method of any one of Examples 7 to 11.

Example 26 may include an apparatus comprising means for performing the method of any one of Examples 19 to 24.

Example 27 may include at least one computer readable storage medium comprising a set of instructions, which when executed by a computing system, cause the computing system to perform the method of any one of Examples 7 to 11.

Example 28 may include at least one computer readable storage medium comprising a set of instructions, which when executed by a computing system, cause the computing system to perform the method of any one of Examples 19 to 24.

Example 29 may include the logarithmic estimation apparatus of Example 1, further including an analog-to-digital converter (ADC), and a logarithmic analyzer.

Example 30 may include the antilogarithmic estimation apparatus of Example 13, further including a digital-to-analog converter (DAC).

Example 31 may include the logarithmic estimation apparatus of Example 1, wherein the logic coupled to the one or more substrates includes transistor channel regions that are positioned within the one or more substrates.

Example 32 may include the antilogarithmic estimation apparatus of Example 13, wherein the logic coupled to the one or more includes transistor channel regions that are positioned within the one or more substrates.

Thus, technology described herein may enable power consumption reduction on a DSP by computing logarithm and antilogarithm based on derivatives. The technology may deliver better accuracy by estimating linear interpolator parameters based on derivatives of the log and antilog functions that find the section where the functions are changing faster. Indeed, better conversion performance and lower complexity may be achieved. For example, in a log conversion, signal-to-quantization noise ratio (SQNR) measurements of 34.72 dB have been achieved, as compared to 30.45 dB measurements for conventional solutions. In an antilog conversion, fixed-point representations of 37.02 dB have been obtained. Moreover, the use of adders instead of multipliers may minimize the impact on signal information. Indeed, during log conversions as few as one adder may be used to perform multiplications.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A, B, C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

1-27. (canceled)

28. A logarithmic estimation apparatus comprising:
one or more substrates; and
logic coupled to the one or more substrates, wherein the logic is implemented in one or more of configurable logic or fixed-functionality hardware logic, the logic coupled to the one or more substrates to:
establish a point of intersection based on a rate of change in a logarithmic function,
generate a first linear estimation of the logarithmic function, wherein the first linear estimation has the point of intersection as an upper bound, and
generate a second linear estimation of the logarithmic function, wherein the second linear estimation has the point of intersection as a lower bound.

29. The logarithmic estimation apparatus of claim 28, wherein the logic coupled to the one or more substrates includes:
a comparator to establish the point of intersection; and
a multiplexer arrangement coupled to the comparator, wherein the multiplexer arrangement is to generate the first linear estimation and the second linear estimation.

30. The logarithmic estimation apparatus of claim 29, wherein the multiplexer arrangement includes:
a first shifter to conduct a divide operation with respect to the first linear estimation;
a second shifter to conduct a divide operation with respect to the second linear estimation; and
a first multiplexer to select between the first shifter and the second shifter.

31. The logarithmic estimation apparatus of claim 30, wherein the multiplexer arrangement includes a second multiplexer to select between an output of the first multiplexer and a negated output of the first multiplexer.

32. The logarithmic estimation apparatus of claim 29, wherein the multiplexer arrangement includes a third multiplexer to select between a first constant value associated with the first linear estimation and a second constant value associated with the second linear estimation.

33. The logarithmic estimation apparatus of claim 28, wherein the logic coupled to the one or more substrates is to select a middle of the rate of change in the logarithmic function as the point of intersection.

34. A method of operating a logarithmic estimation apparatus, comprising:
establishing a point of intersection based on a rate of change in a logarithmic function;
generating a first linear estimation of the logarithmic function, wherein the first linear estimation has the point of intersection as an upper bound; and
generating a second linear estimation of the logarithmic function, wherein the second linear estimation has the point of intersection as a lower bound.

35. The method of claim 34, wherein the point of intersection is established via a comparator, and wherein the first linear estimation and the second linear estimation are generated via a multiplexer arrangement coupled to the comparator.

36. The method of claim 35, further including:
conducting, via a first shifter of the multiplexer arrangement, a divide operation with respect to the first linear estimation;
conducting, via a second shifter of the multiplexer arrangement, a divide operation with respect to the second linear estimation; and
selecting, via a first multiplexer of the multiplexer arrangement, between the first shifter and the second shifter.

37. The method of claim 36, further including selecting, via a second multiplexer of the multiplexer arrangement, between an output of the first multiplexer and a negated output of the first multiplexer.

38. The method of claim 35, further including selecting, via a third multiplexer of the multiplexer arrangement, between a first constant value associated with the first linear estimation and a second constant value associated with the second linear estimation.

39. The method of claim 34, wherein establishing the point of intersection includes selecting a middle of the rate of change in the logarithmic function as the point of intersection.

40. An antilogarithmic estimation apparatus comprising:
one or more substrates; and
logic coupled to the one or more substrates, wherein the logic is implemented in one or more of configurable logic or fixed-functionality hardware logic, the logic coupled to the one or more substrates to:
establish a point of intersection based on a rate of change in an antilogarithmic function, generate a first linear estimation of the antilogarithmic function, wherein the first linear estimation has the point of intersection as an upper bound, and
generate a second linear estimation of the antilogarithmic function, wherein the second linear estimation has the point of intersection as a lower bound.

41. The antilogarithmic estimation apparatus of claim 40, wherein the logic coupled to the one or more substrates includes:
a comparator to establish the point of intersection; and
a multiplexer arrangement coupled to the comparator, wherein the multiplexer arrangement is to generate the first linear estimation and the second linear estimation.

42. The antilogarithmic estimation apparatus of claim 41, wherein the multiplexer arrangement includes:
a first shifter to conduct a first divide operation on a fractional portion of a digital input value with respect to the first linear estimation;
a first multiplexer to select between an output of the first shifter and the fractional portion;
a second shifter to conduct a second divide operation on the fractional portion with respect to the first linear estimation;
a third shifter to conduct a third divide operation on the fractional portion with respect to the second linear estimation;
a second multiplexer to select between an output of the second shifter and an output of the third shifter;
a fourth shifter to conduct a fourth divide operation on the fractional portion with respect to the first linear estimation and the second linear estimation; and
a third multiplexer to select between a first constant value associated with the first linear estimation and a second constant value associated with the second linear estimation.

43. The antilogarithmic estimation apparatus of claim 40, wherein the logic coupled to the one or more substrates includes an input stage to determine a sign of a digital input value and extract a fractional portion from the digital input value based on the sign.

44. The antilogarithmic estimation apparatus of claim 43, wherein the logic coupled to the one or more substrates further includes an output stage to conduct a barrel shift operation on either the first linear estimation or the second linear estimation based on the sign of the digital input value.

45. The antilogarithmic estimation apparatus of claim 40, wherein the logic coupled to the one or more substrates is to select a middle of the rate of change in the antilogarithmic function as the point of intersection.

46. A method of operating an antilogarithmic estimation apparatus, comprising:
establishing a point of intersection based on a rate of change in an antilogarithmic function;
generating a first linear estimation of the antilogarithmic function, wherein the first linear estimation has the point of intersection as an upper bound; and
generating a second linear estimation of the antilogarithmic function, wherein the second linear estimation has the point of intersection as a lower bound.

47. The method of claim 46, wherein the point of intersection is established via a comparator, and wherein the first linear estimation and the second linear estimation are generated by a multiplexer arrangement coupled to the comparator.

48. The method of claim 47, further including:
conducting, via a first shifter, a first divide operation on a fractional portion of a digital input value with respect to the first linear estimation;
selecting, via a first multiplexer, between an output of the first shifter and the fractional portion;
conducting, via a second shifter, a second divide operation on the fractional portion with respect to the first linear estimation;
conducting, via a third shifter, a third divide operation on the fractional portion with respect to the second linear estimation;
selecting, via a second multiplexer, between an output of the second shifter and an output of the third shifter;
conducting, via a fourth shifter, a fourth divide operation on the fractional portion with respect to the first linear estimation and the second linear estimation; and
selecting, via a third multiplexer, between a first constant value associated with the first linear estimation and a second constant value associated with the second linear estimation.

49. The method of claim 46, further including:
determining, via an input stage, a sign of a digital input value; and
extracting, via the input stage, a fractional portion from the digital input value based on the sign.

50. The method of claim 49, further including conducting, via an output stage, a barrel shift operation on either the first linear estimation or the second linear estimation based on the sign of the digital input value.

51. The method of claim 46, wherein establishing the point of interjecting includes selecting a middle of the rate of change in the logarithmic function as the point of intersection.
